(19) United States
(12) Patent Application Publication
(10) Pub. No.: US 2017/0178556 A1
(43) Pub. Date: Jun. 22, 2017

(54) Display Device and Array Substrate

(71) Applicant: BOE Technology Group Co., Ltd., Beijing (CN)

(72) Inventor: Chun Wei Wu, Beijing (CN)

(73) Assignee: BOE Technology Group Co., Ltd., Beijing (CN)

(21) Appl. No.: 15/127,159

(22) PCT Filed: Jan. 13, 2016
(86) PCT No.: PCT/CN2016/070745

§ 371 Date: Sep. 19, 2016

(30) Foreign Application Priority Data
Jul. 10, 2015 (CN) 201510405351.5

(51) Int. Cl. G09G 3/20; H01L 27/12; H01L 27/32; G06F 3/041

(52) U.S. Cl. CPC G09G 3/2092; G06F 3/0412; G06F 3/0416; H01L 27/124; H01L 27/3262; G09G 2360/144; G09G 2300/0426; G09G 2300/0439; G09G 2300/0814

(57) ABSTRACT

A display device and an array substrate are disclosed; the display device includes: pixel units; circuit units configured to output electric signals to the pixel units; and a photodetection unit including a photosensitive element and a switching element which are electrically connected with each other; the photosensitive element is disposed in a non-light-shielding area of the display device and configured to sense light of a predetermined wavelength and generate a light detection signal; the switching element is configured to control an output of the light detection signal; and the circuit units are electrically connected with the switching element and configured to control an on-state or an off-state of the switching element. In the proposal, a photodetection unit may be integrated into the display device.

### TECHNICAL FIELD

Embodiments of the present invention relate to a display device and an array substrate.

### BACKGROUND

Currently, liquid crystal display (LCD) has become a mainstream display product. In general, an LCD comprises: an array substrate and an opposing substrate (e.g., a color filter (CF) substrate) which are disposed opposite to each other, and liquid crystals disposed between the array substrate and the opposing substrate.

Along with the development of display technology, the integration of a display panel with another functional module to form a display device with corresponding function has become a new development trend. For instance, a display panel and a touch module may be integrated to obtain a touch display device, and a display panel and a photodetector may be integrated to obtain a display device with photodetection function.

### SUMMARY

Embodiments of the present invention provide a display device and an array substrate, in which a photodetection unit is integrated into the display device.

At least one embodiment of the present invention provides a display device, having a light-shielding area and a non-light-shielding area, comprising: a plurality of pixel units; circuit units arranged corresponding to the plurality of pixel units and configured to output electric signals to the plurality of pixel units; and a photodetection unit comprising a photosensitive element and a switching element which are electrically connected with each other; the photosensitive element is disposed in the non-light-shielding area and configured to sense light of a predetermined wavelength and generate a light detection signal; the switching element is configured to control an output of the light detection signal generated by the photosensitive element; and the circuit units are electrically connected with the switching element and configured to control an on-state or an off-state of the switching element.

Still at least one embodiment of the present invention provides a display device, having a light-shielding area and a non-light-shielding area, comprising: a plurality of pixel units; a common electrode circuit electrically connected with the plurality of pixel units; and a photodetection unit comprising a photosensitive element which is disposed in the non-light-shielding area; the common electrode circuit is electrically connected with the photosensitive element and configured to control the photosensitive element to maintain an off-state.

Still at least one embodiment of the present invention provides an array substrate, having a light-shielding area and a non-light-shielding area, comprising: a plurality of pixel units; a plurality of signal input terminals electrically connected with the plurality of pixel units and configured to provide electric signals for the plurality of pixel units; and a photodetection unit comprising a photosensitive element and a switching element which are electrically connected with each other, in which the photosensitive element is disposed in the non-light-shielding area and configured to sense light of a predetermined wavelength and generate a light detection signal, and the switching element is configured to control an output of the light detection signal generated by the photosensitive element; one of the plurality of signal input terminals is electrically connected with the switching element and configured to control an on-state or an off-state of the switching element through the electric signals applied to the signal input terminal.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 is a schematic top view of a display device provided by a first embodiment of the present invention;

FIG. 2 is an equivalent circuit diagram of the display device provided by the first embodiment of the present invention;

FIG. 3 is a leakage current graph of an indium gallium zinc oxide (IGZO) thin-film transistor (TFT) under illumination of light of different wavelengths;

FIG. 4 is a schematic sectional view of the display device provided by the first embodiment of the present invention;

FIG. 5 is a schematic top view of a display device provided by a second embodiment of the present invention;

FIG. 6 is an equivalent circuit diagram of the display device provided by the second embodiment of the present invention; and

FIG. 7 is an equivalent circuit diagram of an array substrate provided by a third embodiment of the present invention.

### DETAILED DESCRIPTION

In order to make objects, technical details and advantages of the embodiments of the invention apparent, the technical solutions of the embodiments will be described in a clearly and fully understandable way in connection with the drawings related to the embodiments of the invention. Apparently, the described embodiments are just a part but not all of the embodiments of the invention. Based on the described embodiments herein, those skilled in the art can obtain other embodiment(s), without any inventive work, which should be within the scope of the invention.

Unless otherwise defined, all the technical and scientific terms used herein have the same meanings as commonly understood by one of ordinary skill in the art to which the present invention belongs. The terms “first,” “second,” etc., which are used in the description and the claims of the present application for invention, are not intended to indicate any sequence, amount or importance, but distinguish various components. Also, the terms such as “a,” “an,” etc., are not intended to limit the amount, but indicate the existence of at least one. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly.

The embodiments of the present invention provide a technical solution for integrating a photodetection unit into a display device. Detailed description will be given below.

### First Embodiment

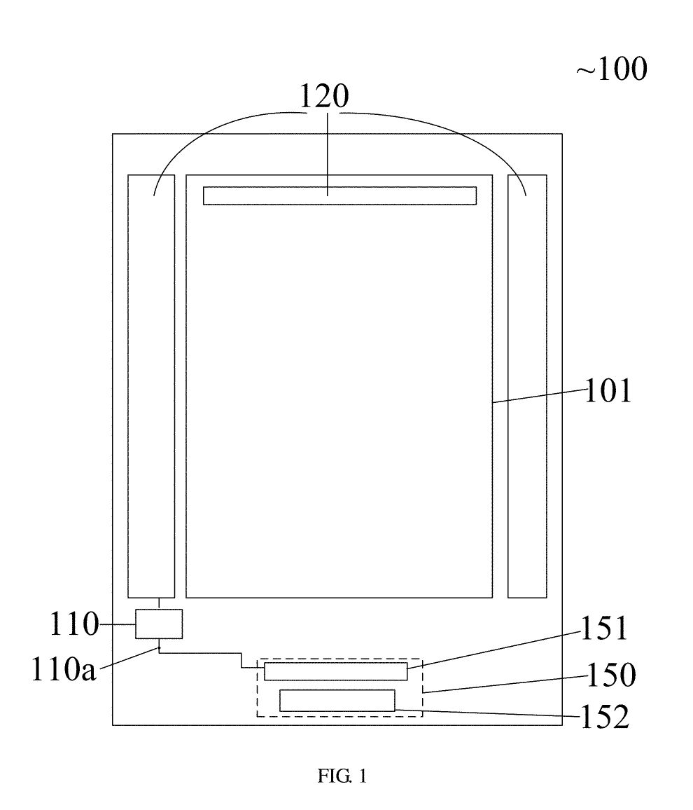

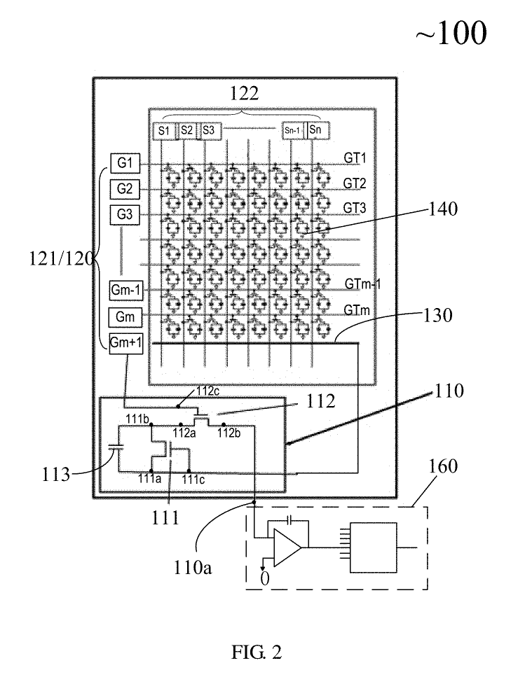

As illustrated in FIGS. 1 and 2, the embodiment provides a display device 100, which comprises a light-shielding area and a non-light-shielding area and comprises a plurality of pixel units 140, circuit units 120 arranged corresponding to the plurality of pixel units 140 and configured to output electric signals to the plurality of pixel units 140 (namely the outputted electric signals are directly applied to the pixel units 140), and a photodetection unit 110 including a photosensitive element 111 and a switching element 112 which are electrically connected with each other. The photosensitive element 111 is disposed in the non-light-shielding area and configured to sense light of a predetermined wavelength and generate a light detection signal; the switching element 112 is configured to control the output of the light detection signal generated by the photosensitive element 111 from an output end 110a of the photodetection unit 110; and the circuit units 120 are electrically connected with the switching element 112 and configured to control the on-state or off-state of the switching element 112. That is to say, when the circuit units 120 control the switching element 112 to switch on, the photodetection unit 110 outputs the light detection signals; and when the circuit units 120 control the switching element 112 to switch off, the photodetection unit 110 does not output the light detection signals.

It should be noted that the light-shielding area and the non-light-shielding area may be related to the light of the predetermined wavelength sensed by the photosensitive element 111, namely an area irradiated by the light with the predetermined wavelength is the non-light-shielding area, and an area not irradiated by the light is the light-shielding area.

For instance, when the display device is configured to sense light of a predetermined wavelength in the external environment in which the display device is provided, the light-shielding area and the non-light-shielding area may be related to a black matrix (BM) (not shown in FIGS. 1 and 2) disposed in the display device 100 and configured to shield light, namely the area of the display device corresponding to the BM is a light-shielding area, and the rest area is a non-light-shielding area.

The embodiment provides a technical solution for integrating a photodetection unit into a display device, which is used for improving the integration of the photodetection unit and the display device.

The display device 100 includes a display area and a non-display area that is disposed along the periphery of the display area 101. The plurality of pixel units 140 is disposed in the display area 101. For instance, the photosensitive element 111 may be disposed in the non-display area, so that the photosensitive element 111 cannot affect the aperture ratio of the display device.

In the embodiment, the display device 100 may be a display device which is provided with a backlight and of a passive light emitting type (e.g., an LCD device) and may also be a display device which is of an active light emitting type (e.g., an organic light-emitting diode (OLED) display device). Correspondingly, the pixel units in the display area may display via back light provided by the backlight, or selfluminous units may be disposed in the display area for display. In this case, the photosensitive element 111 is disposed in the non-display area, so that light emitted by the backlight or light emitted by the light-emitting unit cannot affect the sensing of ambient light of a predetermined wavelength by the photosensitive element 111.

It should be noted that as the black matrix generally includes a part disposed in the display area and a part disposed in the non-display area, and the photosensitive element 111 may be disposed in the non-light-shielding area of the non-display area of the display device 100. FIGS. 1 and 2 only illustrate the range of the display area 101 and the distribution of the circuit units 120, but the embodiment of the present invention is not limited to the cases as shown in FIGS. 1 and 2.

In addition, the light-shielding area and the non-light-shielding area are relevant to a display surface of the display device 100. In a display which is provided with a backlight and of a passive light emitting type, the photosensitive element 111 is disposed at a position, not irradiated by light of the backlight, in the non-light-shielding area, so that the light of the backlight cannot affect the detection of the ambient light by the photosensitive element 111.

Detailed description will be given below to the circuit units 120 with reference to FIG. 2.

For instance, as illustrated in FIG. 2, the plurality of pixel units 140 form a pixel unit array provided having rows and columns, and the circuit units 120 may be gate scanning circuits 121 (as shown in FIG. 2) corresponding to the rows of pixel units 140 or data drive circuits 132 corresponding to the columns of pixel units 140. That is to say, the gate scanning circuits 121 or the data drive circuits 122 may be electrically connected with the switching element 112 and control the on-state and off-state of the switching element 112. In general, in the display period of one frame, the gate scanning circuits 121 sequentially control the on-state and off-state of the thin film transistors (TFTs) in the rows of pixel units (namely progressive scanning), and the data drive circuits 122 control the input of data voltages of the columns of pixel units during the scanning of each row. Thus, electric signals outputted by the gate scanning circuits 121 to the same row of pixel units and those by the data drive circuits 122 to the same column of pixel units are pulse signals (namely discontinuous signals). As the on-state or off-state of the switching element 112 is controlled by the pulse signals outputted by the gate scanning circuits 121 or the data drive circuits 122, the photodetection unit 110 can output the light detection signals at an interval.

For instance, the gate scanning circuits 121 may include a plurality of driving units G1, G2, G3 . . . Gm−1, Gm, Gm+1, and any one of the plurality of driving units may be electrically connected with the switching element 112 and may output a pulse signal to control the on-state or off-state of the switching element 112.

For instance, the plurality of driving units G1, G2, G3 . . . Gm−1, Gm, Gm+1 may be divided into first driving units G1, G2, G3 . . . Gm−1, Gm respectively corresponding to various rows of the array of the pixel units 140 and a second driving unit Gm+1 corresponding to the switching element 112. As the second driving unit Gm+1 is independently arranged for the switching element 112, the large load problem of the connected first driving unit when the switching element 112 is electrically connected with any one of the first driving units corresponding to various rows of pixel units can be avoided.

Gate driver on array (GOA) circuit technology is one of the current commonly used gate scanning circuit technologies. In this technology, gate scanning circuits are directly formed on an array substrate of a display device; therefore, the bonding areas for gate scanning circuits can be eliminated, so that the peripheral wiring space can be removed, and hence the cost can be reduced. In general, GOA circuits are, for instance, disposed on one side or two sides of a display area and include a plurality of GOA circuit units which are, for instance, in series connection; an output end of each GOA circuit unit is connected with, e.g., one gate line, and the gate line is connected to one row of pixel units in the display area, namely each GOA circuit unit corresponds to one row of pixels; and the output end of each GOA circuit unit is also connected to an input end of the next GOA circuit unit and to switch on the next GOA circuit unit, so progressive scanning can be conveniently achieved.

In the display device 100 provided by the embodiment, the gate scanning circuits 121 may adopt the GOA circuit technology. In this case, the plurality of driving units G1, G2, G3 . . . Gm−1, Gm, Gm+1 of the gate scanning circuits 121 are GOA circuit units. The GOA circuit units are in series connection.

Signals in the gate scanning circuits 121/the data drive circuits 122 for controlling the switching element 112 may be achieved by the original signals for the gate scanning circuits 121/the data drive circuits 122 or by the addition of another signal.

For instance, if the gate scanning circuits 121 are GOA circuits, utilizing the original signals of the circuits to control the on-state or off-state of the switching element 112 may include, but not limited to, the following two cases.

First case: supposing that the gate scanning circuits 121 sequentially apply scanning signals (pulse signals) to the gate lines GT (abbreviation of gate line) 1, GT2, GT3 . . . GTm−1, GTm in one scanning process, in this case, the GOA circuit unit (namely one example of the first driving circuit unit, as shown by Gm in FIG. 2) corresponding to the gate line GTm which is the last to be applied with the scanning signal may be directly connected with the switching element 112, and an output signal of this GOA circuit unit is taken as a signal for controlling the on-state or off-state of the switching element 112. In this case, an output end of the GOA circuit unit is connected with the last gate line GTm as well as the switching element 112.

Second case: the GOA circuit unit (namely one example of the second driving circuit unit Gm+1) corresponding to the switching element 112 may be added following the GOA circuit unit corresponding to the last gate line GTm. An output end of the GOA circuit unit is connected with the switching element 112, and an output signal of the GOA circuit unit is taken as a signal for controlling the on-state or off-state of the switching element 112.

In the first cases, the GOA circuit unit not only drives one row of pixel units corresponding to the GOA circuit unit but also drives the switching element 112 and hence has a large load. Compared with the first cases, the second means can avoid the problem of large load of the GOA circuit unit connected with the switching element 112.

It should be noted that the type and the position of the circuit unit as shown in FIG. 2 are only used for illustration. But the embodiment of the present invention is not limited thereto.

On the basis of any above example, for instance, the photodetection unit 110 may further include a capacitor 112 which is configured to store charges produced by the photosensitive element 111 due to light illumination. In this case, the switching element 112 is configured to release the charges stored in the capacitor 113. That is to say, when the switching element 112 is switched off, the light detection signal generated by the photosensitive element 111 are stored in the capacitor 113 in the form of charges; and when the switching element 112 is switched on, the charges stored in the capacitor 113 are released, and the light detection signal are transmitted to the switching element 112 from the capacitor 113. For instance, when an output end of the switching element 112 is taken as an output end of the photodetection unit 110, the light detection signal is outputted from the output end of the switching element 112.

A TFT array is generally disposed in the display area 101. A TFT generally includes a plurality of conductive layers and at least one insulating layer, for instance, a gate metal layer, a source/drain metal layer and a gate insulating layer disposed between the gate metal layer and the source/drain metal layer. Moreover, the capacitor 113 may include two electrodes and an insulating layer disposed between the two electrodes. Therefore, the capacitor 113 may be synchronously formed in the process of forming two conductive layers and one insulating layer of the TFT, so that the manufacturing process can be reduced.

As illustrated in FIG. 1, the display device 100 may further comprise: a light detection signal output circuit 150 which is electrically connected with the output end 110a of the photodetection unit 110 and configured to provide an output interface for the light detection signals sensed by the photosensitive element 111.

For instance, the light detection signal output circuit 150 may include a driver integrated circuit (IC) 151 or a flexible printed circuit board (FPC) 152 which is configured to provide input signals for the display device 100. The driver IC may be configured to provide driving signals for the data drive circuits 122 and the gate scanning circuits 121. As the original driver IC or the FPC of the display device 100 is utilized to provide an output interface for the light detection signals, the integration of the photodetection unit 110 and the display device 100 can be further improved.

For instance, information such as light intensity may be obtained after the subsequent processing on the light detection signals, outputted by the light detection signal output circuit 150, by a signal processing circuit 160. The signal processing circuit 160 may adopt a circuit commonly used by those skilled in the art such as an amplifier and a processor which are connected with each other. No further redundant description will be given here.

The photosensitive element 111 is an element which is sensitive to light illumination. For instance, the photosensitive element 111 may be a photosensitive TFT or a photodiode. When the photosensitive element 111 adopts a TFT, the photosensitive element may be formed along with the TFT in the display area of the display device 100. Therefore, no additional manufacturing process or additional mask plate is required, so that the manufacturing difficulty and the production cost can be reduced. Moreover, the integration of the photodetection unit into the display device can be further improved.

The type of the photosensitive TFT may be selected according to actual demands. For instance, the photosensitive TFT may be an oxide TFT sensitive to ultraviolet (UV) light, an amorphous silicon TFT sensitive to visible light (e.g., light of a predetermined wavelength), a TFT sensitive to infrared light, etc.

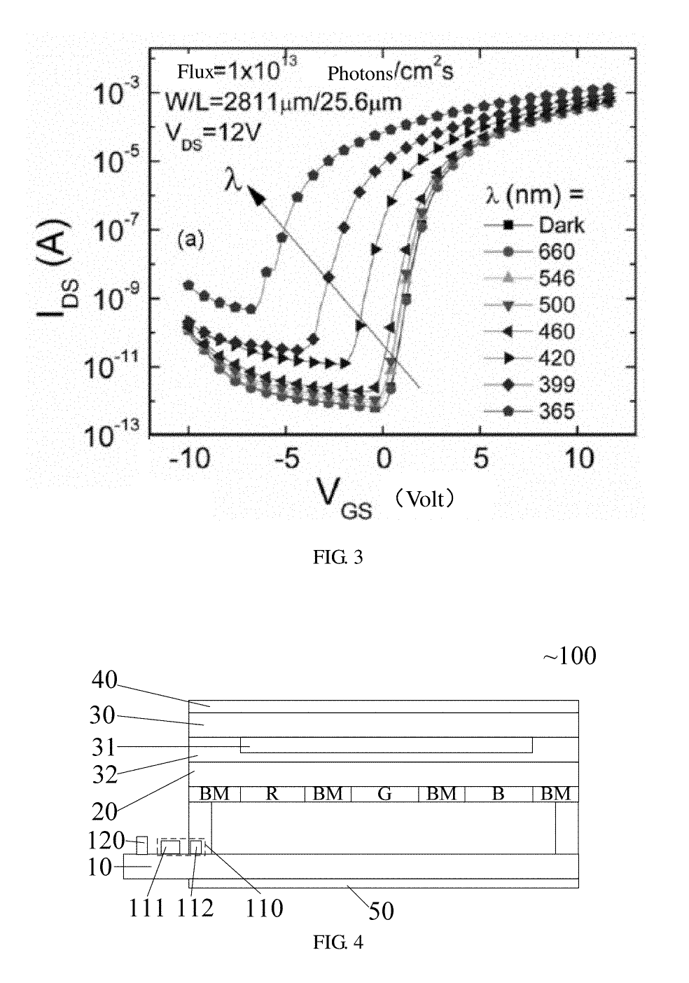

For instance, FIG. 3 is a leakage current graph of an IGZO TFT under the illumination of light of different wavelengths. As seen from FIG. 3, as for UV light with the wavelengths of less than 400 nm, the change of the leakage current of the IGZO TFT along with the light intensity or the UV wavelengths is regular and significant. Thus, an UV light detector may be formed by utilization of the property of the oxide TFT which is relatively sensitive to the UV light. Similarly, as the amorphous silicon TFT is relatively sensitive to visible light, a visible light detector may be formed by utilization of the amorphous silicon TFT.

For instance, the switching element 112 may be a transistor, e.g., a TFT. In this case, the switching element 112 may be formed along with the TFT in the display area of the display device 100. Therefore, no additional manufacturing process or mask plate is required, so that the manufacturing difficulty and the production cost can be reduced. Moreover, the integration of the photodetection unit into the display device can be further improved.

The switching element 112 may adopt an element which is not sensitive to light, so as to avoid the interference upon the output signals of the photodetection unit 110. Or the switching element 112 may also adopt a switching element which is not sensitive to light irradiated to the photosensitive element 111. For instance, the photosensitive element 111 adopts an oxide TFT sensitive to UV light to sense the UV light, and the switching element 112 adopts an amorphous silicon TFT which is not sensitive to the UV light.

In the case where the switching element 112 adopts the element which is not sensitive to light or the element which is not sensitive to the light irradiated to the photosensitive element 111, the switching element 112 may be disposed in the non-light-shielding area of the display device 100.

Or the photosensitive element 111 and the switching element 112 may be the TFTs of same type, so that the photosensitive element and the switching element may be synchronously formed, and hence the manufacturing process can be simplified. For instance, both the photosensitive element 111 and the switching element 112 may adopt oxide TFTs or amorphous silicon TFTs. When the switching element 112 adopts a TFT which is the same type as the photosensitive element 111, the switching element 112 may be disposed in the light-shielding area of the display device 100, so as to avoid the interference upon the output signals of the photodetection unit 110.

In one example of the embodiment as shown in FIG. 2, both the photosensitive element 111 and the switching element 112 are TFTs, and the photodetection unit 110 includes a capacitor 113. Detailed description will be given below to the embodiment with reference to FIG. 2.

As illustrated in FIG. 2, the switching element 112 is a transistor and includes a gate electrode 112c, a source electrode 112a and a drain electrode 112b. The gate electrode 112c of the switching element 112 is electrically connected with a circuit unit (e.g., the driving unit Gm+1 of the gate scanning circuit 121). The source electrode 112a of the switching element 112 is electrically connected with an output end 111b of the photosensitive element 111. Herein, the source electrode and the drain electrode are distinguished according to the current flow direction. The flowing-in end of the current is referred to as the source electrode, and the flowing-out end is referred to as the drain electrode.

For instance, the photosensitive element 111 may be a photosensitive TFT and includes a gate electrode 111c, a source electrode 111a and a drain electrode 111b. The source electrode 112a of the switching element 112 is electrically connected with the drain electrode 111b (output end) of the photosensitive TFT. Herein, the source electrode and the drain electrode are distinguished according to the current flow direction. The flowing-in end of the current is referred to as the source electrode, and the flow-out end is referred to as the drain electrode.

For instance, the photodetection unit 110 may also include a capacitor 113. One end of the capacitor 113 is electrically connected with the drain electrode 111b (output end) of the photosensitive TFT, and the other end is electrically connected with the source electrode 111a (input end) of the photosensitive TFT.

In general, when the photosensitive TFT is irradiated in its off-state, the leakage current is significantly varied along with different wavelengths of incident light, as shown by the left part of each curve in FIG. 3, which becomes favorable to the detection of light of a specific wavelength; and when the photosensitive TFT is irradiated in its on-state, the change of the leakage current along with different wavelengths of the incident light is small, as shown by the right part of each curve in FIG. 3, which is not favorable to the detection of light with specific wavelength. Therefore, in order to improve the detection accuracy of the photodetection unit 110, in the case where the photosensitive element 111 adopts the photosensitive TFT, a small V_{GS} voltage signal may be applied to the photosensitive element 111, so that the photosensitive element can be in the off-state during sensing the light of a predetermined wavelength. On this basis, the photosensitive element 111 may also be configured to continuously sense the light of a predetermined wavelength. In this case, continuous signals may be applied to the photosensitive element 111.

In general, the display device 100 may further comprise a common electrode circuit 130 which is electrically connected with common electrodes in the pixel units 140 and configured to provide a continuous low-voltage signal for the common electrodes.

Therefore, in order to further improve the integration of the photodetection unit 110, the signal of the common electrode circuit 130 may be utilized to control the photosensitive element 111 in the photodetection unit 110 to maintain the off-state. For instance, the common electrode circuit 130 is electrically connected with the plurality of pixel units (the connection relationship between them is not shown in FIG. 2), and the gate electrode 111c and the source electrode 111a of the photosensitive TFT taken as the switching element 111 are electrically connected so as to provide a continuous V_{GS} voltage signal to the photosensitive element 111. Thus, the photosensitive element 111 can continuously sense the light of a predetermined wavelength and maintain the off-state.

For instance, the common electrode circuit 130 includes a common electrode line which is electrically connected with the photosensitive element 111. As the common electrode line is electrically connected with the photosensitive element 111, the original signal of the common electrode circuit 130 may be directly utilized and no additional signal is required.

Taking the display device 100 as shown in FIG. 2 as an example, the working process of the photodetection unit 110 is as follows: as the photosensitive TFT 111 (e.g., one example of the photosensitive element) is disposed in the non-light-shielding area of the display device 100, upon light being irradiated onto the photosensitive TFT 111, the photosensitive TFT 111 generates a light detection signal. At this point, if the switching transistor 112 (one example of the switching element) is in the off-state under the control of the gate scanning circuit 121, the capacitor 113 is charged, so that the light detection signal generated by the photosensitive TFT can be stored in the capacitor 113. If the switching transistor is switched on under the control of the gate scanning circuit 121, the capacitor 113 is discharged, so that the light detection signal can be transmitted to a source electrode 112a of the switching transistor 112 and outputted from a drain electrode 112b of the switching transistor 112.

For instance, when the display device 100 comprises the light detection signal output circuit 150, the light detection signal output circuit 150 may be electrically connected with the drain electrode 112b of the switching element 112 (namely the output end of the photodetection unit 110).

When the photosensitive element 111 is a photodiode and the switching element 112 is a transistor, the source electrode 112a of the switching element 112 may be electrically connected with an output end of the photodiode.

When the photosensitive element 111 is a photodiode, one end of the capacitor 113 of the photodetection unit 110 is electrically connected with an output end of the photodiode while the other end is electrically connected with an input end of the photodiode.

On the basis of any foregoing example, as illustrated in FIG. 4, the display device 100 may further include: a polarizer 40 which may be disposed on an light irradiation side of the photosensitive element 111. Moreover, there is no overlapped area between the photosensitive element 111 and the polarizer 40 in the direction perpendicular to the plane where the display device 100 is located. Thus, the influence of the polarizer 40 on the light irradiated to the photosensitive element 111 can be avoided.

Of course, the display device may generally comprise another polarizer 50 which is opposite to the polarizer 40.

For instance, the display device 100 may comprise an array substrate 10 and an opposing substrate 20. The photodetection unit 110 may be disposed on the array substrate 10 or the opposing substrate 20. For instance, the array substrate may be an array substrate in an LCD device and may also be an OLED array substrate. For instance, the opposing substrate may be a color filter (CF) substrate provided with a black matrix and a CF layer. The CF layer generally includes red (R) CFs, green (G) CFs and blue (B) CFs.

For instance, the display device 100 may further comprise the array substrate 10 but not comprise the opposing substrate 20. In this case, the photodetection unit 110 is disposed on the array substrate 10.

As the array substrate is provided with a TFT array, when both the photosensitive element 111 and the switching element 112 are formed by a TFT, the photodetection unit 110 is disposed on the array substrate 10, and the photosensitive element 111 and the switching element 112 may be also formed in the process of forming the TFTs on the array substrate. Thus, the manufacturing process can be reduced.

As illustrated in FIG. 4, the display device 100 may also include a touch panel 30. The touch panel 30 includes a touch area 31 corresponding to the plurality of pixel units (not shown in FIG. 4), and circuit units 120 which correspond to the pixel units and are configured to provide touch scanning signals for the touch panel 30 and also configured to control the on-state or off-state of the switching element 112.

The touch panel 30 may be disposed on one side of the opposing substrate 20 away from the array substrate 10 and bonded together with the opposing substrate 20 through, e.g., optical adhesive 32, as shown in FIG. 4. Or the touch panel 30 may also be the opposing substrate 20 or the array substrate 10.

It should be noted that the size and the shape of various structures in the accompanying drawings do not represent the true scale and are only intended to illustrate the content of the embodiment. Moreover, other structures of the display device 100 may adopt the conventional arrangement for those skilled in the art. No further redundant description will be given here.

The display device 100 provided by the embodiment may be: any product or component with display function such as an LCD panel, e-paper, an OLED panel, a touch display panel, a mobile phone, a tablet PC, a TV, a display, a notebook computer, a digital picture frame and a navigator.

### Second Embodiment

The embodiment provides a display device 200. The difference of the present embodiment from the display device 100 provided by the first embodiment is that: the photodetection unit does not include the switching element for controlling the output of the light detection signals from the output end of the photodetection unit, so the light detection signal may be continuously outputted but not discontinuously outputted. Moreover, as the light detection signal can be continuously outputted, a capacitor for storing charges produced by the photosensitive element is not required any more to be disposed between the input end and the output end of the photosensitive element in the photodetection unit.

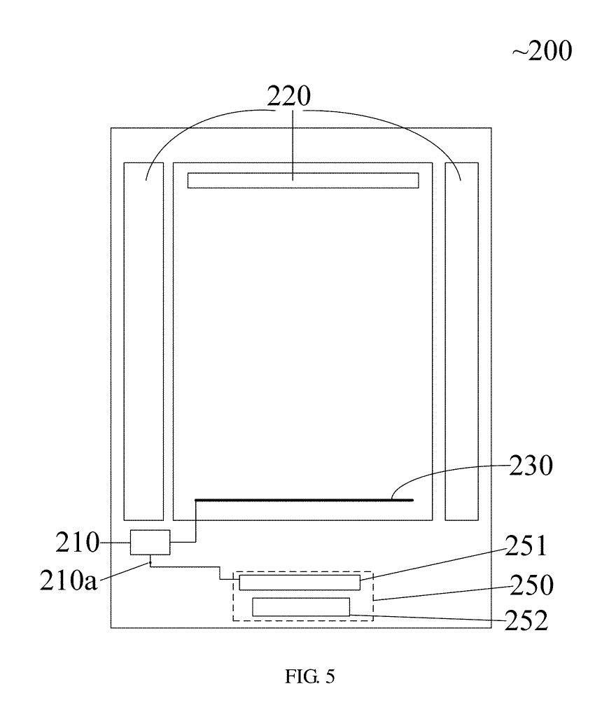

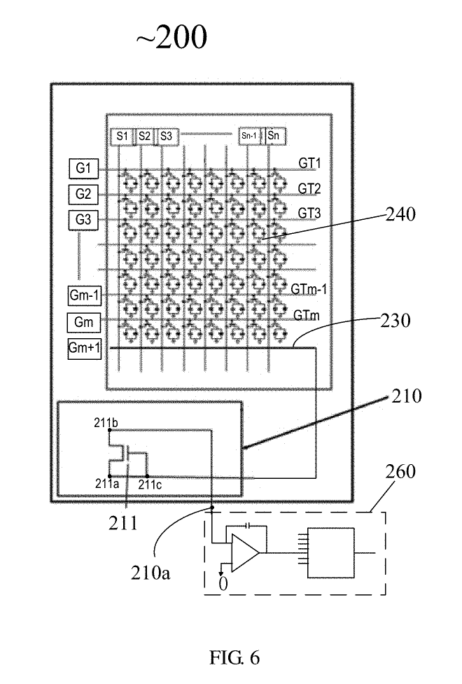

As illustrated in FIGS. 5 and 6, the display device 200 includes a light-shielding area and a non-light-shielding area and comprises a plurality of pixel units 240, a common electrode circuit 230 electrically connected with the plurality of pixel units (the connection relationship between the common electrode circuit and the pixel units is not shown in the figure), and a photodetection unit 210 provided with a photosensitive element 211. The photosensitive element 211 is disposed in the non-light-shielding area. The common electrode circuit 230 is electrically connected with the photosensitive element 211 to control the photosensitive element 211 to maintain the off-state.

For instance, the photosensitive element 211 is a photosensitive TFT, e.g., an oxide TFT or an amorphous silicon TFT.

For instance, when the photosensitive element 211 is a photosensitive TFT, the common electrode circuit 230 may be connected with a gate electrode 211c and a source electrode 211a of the photosensitive TFT, so that the photosensitive TFT can maintain the off-state. Therefore, when light is irradiated to the photosensitive TFT, the photosensitive TFT may generate a large leakage current (namely light detection signal).

For instance, the common electrode circuit 230 may include a common electrode line which may be electrically connected with the gate electrode 211c and the source electrode 211a of the photosensitive TFT.

As illustrated in FIG. 5, the display device 200 may further comprise a light detection signal output circuit 250 which is electrically connected with an output end 210a of a photodetection unit 210 and configured to provide an output interface for light detection signal produced by the photosensitive element 211.

For instance, the light detection signal output circuit 250 may include a driver IC 251 or an FPC 252 which is configured to provide input signals for the display device 200. The driver IC may provide driving signals to data drive circuits and gate scanning circuits. As the original driver IC or FPC of the display device 200 is utilized to provide an output interface for the light detection signals, the integration of the photodetection unit 210 and the display device 200 can be further improved.

For instance, light intensity may be obtained after the subsequent processing upon the light detection signals, outputted from the light detection signal output circuit 250, by a signal processing circuit 260. The signal processing circuit 260 may adopt a circuit commonly used by those skilled in the art such as an amplifier and a processor which are connected with each other. No further redundant description will be given here.

The settings of the components in the embodiment may refer to relevant description in the embodiment. No further redundant description will be given here.

### Third Embodiment

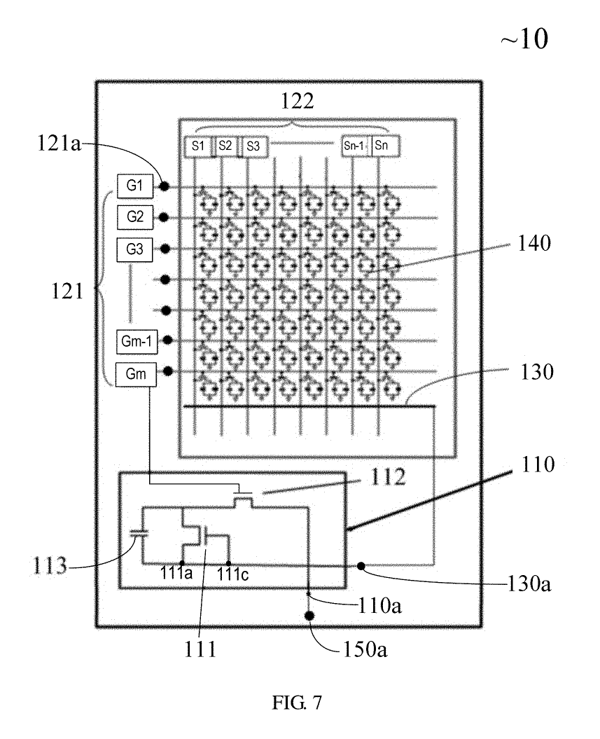

The present embodiment provides an array substrate 10 which may be applied to the display device provided by the first embodiment. As illustrated in FIG. 7, the array substrate 10 includes a light-shielding area and a non-light-shielding area and comprises: a plurality of pixel units 140, a plurality of signal input terminals 121a which are electrically connected with the plurality of pixel units 140 and configured to provide electric signals for the plurality of pixel units 140, and a photodetection unit 110 including a photosensitive element 111 and a switching element 112 which are electrically connected with each other. The photosensitive element 111 is disposed in the non-light-shielding area and configured to sense light of a predetermined wavelength and generate a light detection signal. The switching element 112 is configured to control the output of the light detection signal generated by the photosensitive element 111. One of the plurality of signal input terminals is electrically connected with the switching element 112 and configured to control the on-state or off-state of the switching element 112 through the electric signal applied to the signal input terminal.

For instance, the plurality of signal input terminals 121a are gate scanning signal input terminals or data signal input terminals. For instance, gate scanning circuits 121 or data drive circuits 122 may be disposed on the array substrate 10. In this case, the signal input terminals 121a are electrically connected with the gate scanning circuits 121 or the data drive circuits 122. Correspondingly, the electric signals applied to the signal input terminals 121a are signals outputted by the gate scanning circuits 121 or the data drive circuits 122.

The array substrate 10 may adopt GOA circuit technology. In this case, the array substrate 10 may comprise: a plurality of array substrate row driving circuit units G1, G2, G3,,,Gm−1, Gm. The array substrate row driving circuit units are in series connection and are correspondingly electrically connected with the plurality of signal input terminals 121a. In this case, the electric connection between one of the plurality of signal input terminals 121a and the switching element 112 may refer to the relevant description in the first embodiment. No further redundant description will be given here.

For instance, the array substrate 10 may further comprise a light detection signal output terminal 150a. In order to further improve the integration of the photodetection unit 110 and the array substrate 10, the light detection signal output terminal 150a may be electrically connected with a driver IC or an FPC for providing input signals for the array substrate 10. As the original driver IC or FPC of the display device 100 is utilized to provide an output interface for the light detection signals, the integration of the photodetection unit 110 and the array substrate 10 can be further improved.

As similar to the first embodiment, the switching element 112 may be a transistor, and the photosensitive element 111 may be a photosensitive TFT or a photodiode.

When the photosensitive element 111 is a photosensitive TFT, the array substrate 10 may further comprise a common electrode signal input terminal 130a which is electrically connected with a gate electrode 111c and a source electrode 111a of the photosensitive TFT. Signals outputted by the common electrode signal input terminal are configured to control the off-state of the photosensitive element 111, so that the photosensitive element 111 can continuously sense light of a predetermined wavelength and maintain the off-state and can generate a large leakage current when irradiated by the light of the predetermined wavelength.

For instance, the array substrate 10 may comprise a common electrode circuit. The common electrode circuit 130 (e.g., a common electrode line) is electrically connected with the common electrode signal input terminal 130a.

As the array substrate provided by the embodiment may be applied to the display device 100 provided by the first embodiment, the embodiments of the components in the array substrate may refer to relevant description in the first embodiment. No further redundant description will be given here.

What are described above is related to the illustrative embodiments of the disclosure only and not limitative to the scope of the disclosure; the scopes of the disclosure are defined by the accompanying claims.

The application claims priority to the Chinese patent application No. 201510405351.5, filed Jul. 10, 2015, the entire disclosure of which is incorporated herein by reference as part of the present application.

1. A display device, having a light-shielding area and a non-light-shielding area, comprising:
a plurality of pixel units;
circuit units arranged corresponding to the plurality of pixel units and configured to output electric signals to the plurality of pixel units; and
a photodetection unit comprising a photosensitive element and a switching element which are electrically connected with each other, wherein
the photosensitive element is disposed in the non-light-shielding area and configured to sense light of a predetermined wavelength and generate a light detection signal; the switching element is configured to control an output of the light detection signal generated by the photosensitive element; and
the circuit units are electrically connected with the switching element and configured to control an on-state or an off-state of the switching element.

2. The display device according to claim 1, wherein the display device comprises a display area and a non-display area disposed on a periphery of the display area; the plurality of pixel units are disposed in the display area; and the photosensitive element is disposed in the non-display area.

3. The display device according to claim wherein
the plurality of pixel units are arranged to form a pixel unit array having a plurality of rows and a plurality of columns; and the circuit units are gate scanning circuits corresponding to the rows of pixel units or data drive circuits corresponding to the columns of pixel units.

4. The display device according to claim 3, wherein the gate scanning circuits comprise a plurality of driving units; and one of the plurality of driving units is electrically connected with the switching element and is capable of outputting a pulse signal to control the on-state or the off-state of the switching element.

5. The display device according to claim 4, wherein the plurality of driving units comprise first driving units respectively corresponding to the rows of the pixel unit array and a second driving unit corresponding to the switching element.

6. The display device according to claim 5, wherein the plurality of driving units are a plurality of array substrate row driving circuit units which are in serious connection.

7. The display device according to claim 1, further comprising a touch panel, wherein the touch panel comprises a touch area corresponding to the plurality of pixel units; and the circuit units are configured to provide touch scanning signals for the touch panel.

8. The display device according to claim 1, wherein the switching element is a transistor and comprises a gate electrode, a source electrode and a drain electrode; the gate electrode of the switching element is electrically connected with the circuit units; and the source electrode is electrically connected with an output end of the photosensitive element.

9.-11. (canceled)

12. The display device according to claim 8, wherein the photosensitive element is a photosensitive TFT or a photodiode; and a source electrode of the switching element is electrically connected with an output end of the photosensitive TFT or the photodiode.

13. The display device according to claim 12, wherein the photosensitive TFT is an oxide TFT or an amorphous silicon TFT.

14. (canceled)

15. The display device according to claim 12, further comprising:
a common electrode circuit electrically connected with the plurality of pixel units and electrically connected with a gate electrode and a source electrode of the photosensitive TFT.

16. (canceled)

17. The display device according to claim 1, wherein the photodetection unit further comprises a capacitor which is configured to store charges produced by the photosensitive element; and the switching element is also configured to control the release of the charges stored in the capacitor.

18. The display device according to claim 1, further comprising: a light detection signal output circuit which is electrically connected with an output end of the photodetection unit.

19. The display device according to claim 1, further comprising: a polarizer, wherein there is no overlapped area between the photosensitive element and the polarizer in a direction perpendicular to a plane where the display device is located.

20.-21. (canceled)

22. A display device, having a light-shielding area and a non-light-shielding area, comprising:
a plurality of pixel units;
a common electrode circuit electrically connected with the plurality of pixel units; and
a photodetection unit comprising a photosensitive element which is disposed in the non-light-shielding area, wherein
the common electrode circuit is electrically connected with the photosensitive element and configured to control the photosensitive element to maintain an off-state.

23. The display device according to claim 22, wherein the photosensitive element is a photosensitive thin film transistor (TFT).

24. The display device according to claim 23, wherein the photosensitive TFT comprises a gate electrode, a source electrode and a drain electrode; and the common electrode circuit is electrically connected with the gate electrode and the source electrode.

25. (canceled)

26. An array substrate, having a light-shielding area and a non-light-shielding area, comprising:
a plurality of pixel units;
a plurality of signal input terminals electrically connected with the plurality of pixel units and configured to provide electric signals for the plurality of pixel units; and
a photodetection unit comprising a photosensitive element and a switching element which are electrically connected with each other, in which the photosensitive element is disposed in the non-light-shielding area and configured to sense light of a predetermined wavelength and generate a light detection signal, and the switching element is configured to control an output of the light detection signal generated by the photosensitive element, wherein
one of the plurality of signal input terminals is electrically connected with the switching element and configured to control an on-state or an off-state of the switching element through the electric signals applied to the signal input terminal.

27. The array substrate according to claim 26, wherein the plurality of signal input terminals are gate scanning signal input terminals or data signal input terminals.

28. The array substrate according to claim 26, further comprising a plurality of array substrate row driving circuit units, wherein the array substrate row driving circuit units are in series connection and respectively electrically connected with the plurality of signal input terminals.
